(19) United States
(12) Patent Application Publication
(10) Pub. No.: US 2016/0349537 A1
(43) Pub. Date: Dec. 1, 2016

(54) Method for manufacturing blue light proof optical lens

(71) Applicant: OURLOOK (ZHANGHOU) OPTICAL TECHNOLOGY CO., LTD, Zhangzhou, Fujian (CN)

(72) Inventor: Xiaotong WU, Zhangzhou, Fujian (CN)

(21) Appl. No.: 15/118,095

(22) PCT Filed: Dec. 19, 2014
(86) PCT No.: PCT/CN2014/094308

§ 371 Date: Aug. 10, 2016

(30) Foreign Application Priority Data
May 30, 2014 (CN) 201410238603.5

(51) Int. Cl. G02C 7/10; G02B 1/14; G02B 1/18; C23C 14/14; C23C 14/02; C23C 14/08; C23C 14/10; C23C 14/58; G02B 1/12; C23C 14/30

(52) U.S. Cl. CPC G02C 7/104; G02B 1/12; G02B 1/14; G02B 1/18; C23C 14/30; C23C 14/021; C23C 14/083; C23C 14/10; C23C 14/584; C23C 14/5886; C23C 14/14

(57) ABSTRACT

A method for manufacturing a blue light proof optical lens forms the blue light proof optical lens by providing vapor deposition on both an external surface and an internal surface of a polymer resin substrate (1), including steps of: 1) cleaning the substrate (1); 2) drying the substrate (1) after cleaning; 3) before deposition, cleaning the substrate (1) in a vacuum chamber of a vacuum deposition machine; and 4) coating the substrate (1), including steps of coating an external film system and coating an internal film system. The blue light proof optical lens manufactured with the method is able to prevent blue lights and ultraviolet from damaging human bodies, and has anti-oil as well as autonomous optical control functions.

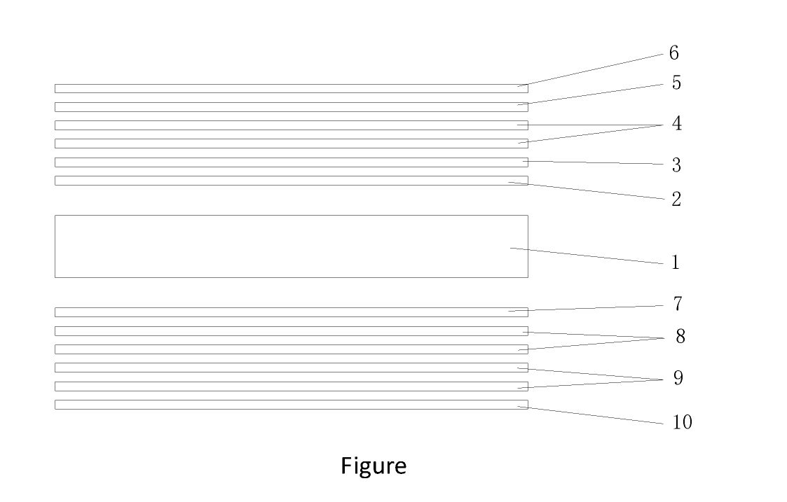

### CROSS REFERENCE OF RELATED APPLICATION

This is a U.S. National Stage under 35 U.S.C 371 of the International Application PCT/CN2014/094308, filed Dec. 19, 2014, which claims priority under 35 U.S.C. 119(a-d) to CN 201410238603.5, filed May 30, 2014.

### BACKGROUND OF THE PRESENT INVENTION

Field of Invention

The present invention relates to a method for manufacturing a blue light proof optical lens.

Description of Related Arts

It is known that ultraviolet can cause damage to the eyes, and long-term UV exposure can cause cataracts. Similarly, blue light is a high-energy visible light having a wavelength of 400-500 nm, which can penetrate the cornea as well as the eye lens, and directly access to the retina. The blue light may stimulate the retina to produce a large number of radical ions, causing atrophy of retinal pigment epithelium and death of light sensitive cells. The retinal pigment epithelium has a strong absorption effect on radiation of blue light region, and absorbing blue light radiation will cause atrophy of the retinal pigment epithelium, which is one of the main reasons of macular degeneration. The higher the blue light radiation component is, the greater the visual cells are damaged. The atrophy of retinal pigment epithelium will blur retinal images while ciliary muscle will make continuous adjustment to the blurred images, leading to increased work intensity of the ciliary muscle and visual fatigue. Both the ultraviolet and the blue light can cause visual fatigue, wherein vision will gradually decline, leading to early onset cataracts and spontaneously macular degenerations such as visual aningeresting, photophobia, fatigue, etc.

Conventionally, optical lenses available on the market only have single function, which are mainly for vision correction without blue light and ultraviolet proof functions;

and there is no plain lens or optical lens for providing blue light and ultraviolet proof to common people.

### SUMMARY OF THE PRESENT INVENTION

An object of the present invention is to provide a method for manufacturing a blue light proof optical lens, wherein the blue light proof optical lens manufactured with the method is able to prevent blue lights and ultraviolet from damaging human bodies, and has anti-oil as well as autonomous optical control functions.

Accordingly, in order to accomplish the above object, the present invention provides a method for manufacturing a blue light proof optical lens, which forms the blue light proof optical lens by providing vapor deposition on both an external surface and an internal surface of a substrate, comprising steps of:

1) cleaning the substrate;

2) drying the substrate after cleaning; specifically, dehydrating the substrate with isopropanol after cleaning, and then slowly pulling out of the isopropanol for drying;

3) before deposition, cleaning the substrate in a vacuum chamber of a vacuum deposition machine; specifically, after the substrate is dried by slowly pulling out of the isopropanol, placing the substrate inside the vacuum chamber of the vacuum deposition machine, adjusting a vacuum degree inside the vacuum chamber to no more than 9.5×10⁻³Pa, then cleaning the substrate with an ion source; and

4) coating the substrate, comprising steps of coating an external film system and coating an internal film system; wherein

A) coating the external film system comprises steps of: coating an impact strengthening external film, coating an ultraviolet proof external film, coating a blue light proof external film, coating an optical regulation external film, and coating an anti-oil external film in sequence; wherein

A1) coating the impact strengthening external film comprises steps of: adjusting the vacuum degree in the vacuum chamber to no more than 2.0×10⁻³Pa, evaporating an impact strengthening film material with an electron gun; and then depositing the impact strengthening film material on the external film surface of the substrate in a nano-molecular form with the ion source, so as to form the impact strengthening external film; wherein a thickness thereof is 0.1-600 nm; and the impact strengthening film material is silicon oxide;

A2) coating the ultraviolet proof external film comprises steps of: evaporating an ultraviolet proof film material with the electron gun; and then depositing the ultraviolet proof film material on the impact strengthening external film of the step A1) in the nano-molecular form with the ion source, so as to form the ultraviolet proof external film; wherein a thickness thereof is 0.1-600 nm; and the ultraviolet proof film material comprises silicon oxide with a content of 20-80%, and zirconium oxide with a content of 20-80%;

A3) coating the blue light proof external film comprises steps of: evaporating a blue light proof film material with the electron gun; and then depositing the blue light proof film material on the ultraviolet proof external film of the step A2) in the nano-molecular form with the ion source, so as to form the blue light proof external film; wherein a thickness thereof is 0.1-600 nm; and the blue light proof film material comprises tin oxide with a content of 30-60%, rubidium with a content of 10-40%, and platinum with a content of 10-40%;

wherein the step A3) is repeated at least once for forming a blue light proof external film stack with at least two layers;

A4) coating the optical regulation external film comprises steps of: evaporating an optical regulation film material with the electron gun; and then depositing the optical regulation film material on the blue light proof external film of the step A3) in the nano-molecular form with the ion source, so as to form the optical regulation external film; wherein a thickness thereof is 0.1-600 nm; and the blue light proof film material comprises aluminum with a content of 40-60%, and silicon oxide with a content of 40-60%;

A5) coating the anti-oil external film comprises steps of: evaporating an anti-oil film material with the electron gun; and then depositing the anti-oil film material on the optical regulation external film of the step A4) in the nano-molecular form with the ion source, so as to form the anti-oil external film; wherein a thickness thereof is 0.1-600 nm; and the blue light proof film material comprises magnesium fluoride with a content of 60-80%, and zirconium oxide with a content of 20-40%;

after coating the anti-oil external film, the external film system is complete, and the internal film system is to be coated;

B) coating the internal film system comprises steps of: coating an impact strengthening internal film, coating an ultraviolet proof internal film, coating a blue light proof internal film, and coating an anti-oil internal film in sequence; wherein

B1) coating the impact strengthening internal film comprises steps of: evaporating the impact strengthening film material with the electron gun; and then depositing the impact strengthening film material on the internal film surface of the substrate in the nano-molecular form with the ion source, so as to form the impact strengthening internal film; wherein a thickness thereof is 0.1-600 nm; and the impact strengthening film material is silicon oxide;

B2) coating the ultraviolet proof internal film comprises steps of: evaporating the ultraviolet proof film material with the electron gun; and then depositing the ultraviolet proof film material on the impact strengthening internal film of the step B1) in the nano-molecular form with the ion source, so as to form the ultraviolet proof internal film; wherein a thickness thereof is 0.1-600 nm; and the ultraviolet proof film material comprises silicon oxide with a content of 20-80%, and zirconium oxide with a content of 20-80%;

B3) coating the blue light proof internal film comprises steps of: evaporating the blue light proof film material with the electron gun; and then depositing the blue light proof film material on the ultraviolet proof internal film of the step B2) in the nano-molecular form with the ion source, so as to form the blue light proof internal film; wherein a thickness thereof is 0.1-600 nm; and the blue light proof film material comprises tin oxide with a content of 30-60%, rubidium with a content of 10-40%, and platinum with a content of 10-40%;

wherein the step B3) is repeated at least once for forming a blue light proof internal film stack with at least two layers;

B4) coating the anti-oil internal film comprises steps of: evaporating the anti-oil film material with the electron gun; and then depositing the anti-oil film material on the blue light proof internal film of the step B3) in the nano-molecular form with the ion source, so as to form the anti-oil internal film; wherein a thickness thereof is 0.1-600 nm;

and the blue light proof film material comprises magnesium fluoride with a content of 60-80%, and zirconium oxide with a content of 20-40%.

In the step 1), cleaning the substrate specifically comprises steps of:

a) cleaning the substrate with organic detergent, and using ultrasound for assisting;

b) after the step a), cleaning the substrate with water-based detergent, and using the ultrasound for assisting; and

c) after the step b), rinsing the substrate with city water and distilled water in sequence.

The substrate is formed with polymer resin.

Effects of the impact strengthening external film and the impact strengthening internal film are as follows: 1) impact resistance of the lens is increased, which avoids harming eyes due to cracking; 2) adhesion of the lens is increased, which has a sufficient binding effect as a medium for the next film, so as to avoid leafing.

Effects of the ultraviolet proof external film and the ultraviolet proof internal film are as follows: anti-corrosion, anti-oxidation and anti-ultraviolet.

Effects of the blue light proof external film and the blue light proof internal film are as follows: an absorption rate of blue lights with wavelengths of 380-500 nm is above 33%, and harmful rays are also absorbed, in such a manner that vision is clear as well as bright, the eyes are effectively protected, and visual fatigue is mitigated.

Effects of the optical regulation external film are as follows: lens principle of a zoom camera is used, wherein under an environment which is too dim or too bright, the optical regulation film has a self-regulation effect for light balancing, in such a manner that a user quickly adapts to the environment; long time looking is harmful, looking too long at a computer or LCD screen will lead to visual fatigue such as sore eyes, dry eyes, eye swelling, and tearing; optical regulation film is able to relieve such visual fatigue.

Effects of the anti-oil external film and the anti-oil internal film are as follows: the anti-oil film covers other films on the surfaces of the substrate, and decreases a contact area between water or oil and the lens, in such a manner that oil and water drops are difficult to adhere on the surfaces of the lens.

The present invention uses principles of electron beam vacuum vapor deposition, wherein charged particles have certain kinetic energy after being accelerated in an electric field, so as to form an electrode leading ions to the substrate for coating. Furthermore, the electron gun bombards highly-pure metal oxide components with a high temperature, in such a manner that the evaporated nano-molecules move along a certain direction and finally deposit on the substrate for forming a film. The present invention takes advantage of special distribution of a magnetic field to control electron trajectories in the electric field for improving coating techniques, in such a manner that film thickness and uniformity are controllable, film density is sufficient, cohesion is strong, and purity is high.

According to the present invention, the optical lens is coated with the ultraviolet proof films and the blue light proof films which avoid damages on eyes. Therefore, when users, no matter visual correction is needed or not, are using LED lights, computers, cell phones, televisions and microwave ovens, the optical lens keeps effective and comprehensively avoids radiation on human eyes and brains due to harmful blue light and ultraviolet, so as to ensure body health and inhibit myopia worsening. Furthermore, visual correction and myopia inhibit functions of conventional optical lenses are kept, for maintaining a clear vision. In addition, the films of the present invention cooperates with each other for finally forms a white transparent layer (platinum layer) on the optical lens, while the conventional optical lenses are usually coated with blue or green films. That is to say, bottom colors of the conventional optical lenses are blue and green, while the blue or green film will confuse visual authenticity when looking at screens and light sources due to blue or green bottom color adhesion. Similarly, blue or green halos will appear when looking at lights. The optical lens with the white transparent film layer (platinum layer) is able to compensate for the visual effect inadequacies of the conventional optical lenses (with the blue or green film). However, optical lens for filtering harmful blue light is commercially unavailable. According to the present invention, the lens not only effectively filters over 33% of the harmful blue light, but also remain a transmission rate above 79%, which is greatly conducive to visual clarity and authenticity, and relieves visual fatigue by filtering the harmful blue light.

### BRIEF DESCRIPTION OF THE DRAWINGS

Referring to drawing and preferred embodiments, the present invention is further illustrated.

FIGURE is an exploded view of the present invention.

### DETAILED DESCRIPTION OF THE PREFERRED EMBODIMENT

Referring to Figure, a method for manufacturing a blue light proof optical lens is provided, which forms the blue light proof optical lens by providing vapor deposition on both an external surface and an internal surface of a substrate 1, comprising steps of:

1) cleaning the substrate 1;

2) drying the substrate 1 after cleaning; specifically, dehydrating the substrate 1 with isopropanol after cleaning, and then slowly pulling out of the isopropanol for drying; it should be noticed that after slowly pulling the substrate 1 out of the isopropanol for drying, water spots remain on dried lenses of some certain kinds, which depends on a purity of the isopropanol and air humidity;

3) before deposition, cleaning the substrate 1 in a vacuum chamber of a vacuum deposition machine; specifically, after the substrate 1 is dried by slowly pulling out of the isopropanol, placing the substrate 1 inside the vacuum chamber of the vacuum deposition machine, adjusting a vacuum degree inside the vacuum chamber to no more than 9.5×10⁻³Pa, then cleaning the substrate 1 with an ion source, in such a manner that surface besmirch on the substrate 1 is thoroughly cleaned and cohesion of the substrate 1 is improved before coating; and

4) coating the substrate 1, comprising steps of coating an external film system and coating an internal film system; wherein

A) coating the external film system comprises steps of: coating an impact strengthening external film 2, coating an ultraviolet proof external film 3, coating a blue light proof external film 4, coating an otical regulation external film 5, and coating an anti-oil external film 6 in sequence; wherein

A1) coating the impact strengthening external film 2 comprises steps of: adjusting the vacuum degree in the vacuum chamber to no more than 2.0×10⁻³Pa, evaporating an impact strengthening film material with an electron gun; and then depositing the impact strengthening film material on the external film surface of the substrate 1 in a nano-molecular form with the ion source, so as to form the impact strengthening external film 2; wherein a thickness thereof is 0.1-600 nm; and the impact strengthening film material is silicon oxide;

A2) coating the ultraviolet proof external film 3 comprises steps of: evaporating an ultraviolet proof film material with the electron gun; and then depositing the ultraviolet proof film material on the impact strengthening external film 2 of the step A1) in the nano-molecular form with the ion source, so as to form the ultraviolet proof external film 3; wherein a thickness thereof is 0.1-600 nm; and the ultraviolet proof film material comprises silicon oxide with a content of 20-80%, and zirconium oxide with a content of 20-80%;

A3) coating the blue light proof external film 4 comprises steps of: evaporating a blue light proof film material with the electron gun; and then depositing the blue light proof film material on the ultraviolet proof external film 3 of the step A2) in the nano-molecular form with the ion source, so as to form the blue light proof external film 4; wherein a thickness thereof is 0.1-600 nm; and the blue light proof film material comprises tin oxide with a content of 30-60%, rubidium with a content of 10-40%, and platinum with a content of 10-40%;

wherein the step A3) is repeated at least once for forming a blue light proof external film 4 stack with at least two layers;

A4) coating the otical regulation external film 5 comprises steps of: evaporating an optical regulation film material with the electron gun; and then depositing the optical regulation film material on the blue light proof external film 4 of the step A3) in the nano-molecular form with the ion source, so as to form the otical regulation external film 5; wherein a thickness thereof is 0.1-600 nm; and the blue light proof film material comprises aluminum with a content of 40-60%, and silicon oxide with a content of 40-60%;

A5) coating the anti-oil external film 6 comprises steps of: evaporating an anti-oil film material with the electron gun; and then depositing the anti-oil film material on the otical regulation external film 5 of the step A4) in the nano-molecular form with the ion source, so as to form the anti-oil external film 6; wherein a thickness thereof is 0.1-600 nm; and the blue light proof film material comprises magnesium fluoride with a content of 60-80%, and zirconium oxide with a content of 20-40%;

after coating the anti-oil external film 6, the external film system is complete, and the internal film system is to be coated;

B) coating the internal film system comprises steps of: coating an impact strengthening internal film 7, coating an ultraviolet proof internal film 8, coating a blue light proof internal film 9, and coating an anti-oil internal film 10 in sequence; wherein

B1) coating the impact strengthening internal film 7 comprises steps of: evaporating the impact strengthening film material with the electron gun; and then depositing the impact strengthening film material on the internal film surface of the substrate 1 in the nano-molecular form with the ion source, so as to form the impact strengthening internal film 7; wherein a thickness thereof is 0.1-600 nm; and the impact strengthening film material is silicon oxide;

B2) coating the ultraviolet proof internal film 8 comprises steps of: evaporating the ultraviolet proof film material with the electron gun; and then depositing the ultraviolet proof film material on the impact strengthening internal film 7 of the step B1) in the nano-molecular form with the ion source, so as to form the ultraviolet proof internal film 8; wherein a thickness thereof is 0.1-600 nm; and the ultraviolet proof film material comprises silicon oxide with a content of 20-80%, and zirconium oxide with a content of 20-80%;

B3) coating the blue light proof internal film 9 comprises steps of: evaporating the blue light proof film material with the electron gun; and then depositing the blue light proof film material on the ultraviolet proof internal film 8 of the step B2) in the nano-molecular form with the ion source, so as to form the blue light proof internal film 9; wherein a thickness thereof is 0.1-600 nm; and the blue light proof film material comprises tin oxide with a content of 30-60%, rubidium with a content of 10-40%, and platinum with a content of 10-40%;

wherein the step B3) is repeated at least once for forming a blue light proof internal film 9 stack with at least two layers;

B4) coating the anti-oil internal film 10 comprises steps of: evaporating the anti-oil film material with the electron gun; and then depositing the anti-oil film material on the blue light proof internal film 9 of the step B3) in the nano-molecular form with the ion source, so as to form the anti-oil internal film 10; wherein a thickness thereof is 0.1-600 nm; and the blue light proof film material comprises magnesium fluoride with a content of 60-80%, and zirconium oxide with a content of 20-40%.

In the step 1), cleaning the substrate 1 specifically comprises steps of:

a) cleaning the substrate 1 with organic detergent, and using ultrasound for assisting;

b) after the step a), cleaning the substrate 1 with water-based detergent, and using the ultrasound for assisting; and

c) after the step b), rinsing the substrate 1 with city water and distilled water in sequence.

The substrate 1 is formed with polymer resin. A resin (which is a mixture of a plurality of polymer compounds) material is processed with precise chemical processes for forming the polymer resin substrate 1; wherein advantages thereof are as follows: 1) strong impact resistance and cracking resistance with an impact endurance of 8-10 kg/cm²; 2) sufficient transmission, while lights harmful to human eyes are effectively filtered after coating; 3) light weight with a density of 0.83-1.5 g/cm²; 4) convenient machining such as highly refractive (1.499-1.74) optical lenses and aspherical optical lenses.

During coating processes of the present invention, light wave changes and perspectivity between 280-760 nm are monitored with multi-wavelength full spectrum end analysis. With a quartz crystal monitoring system, coating material evaporation rate frequencies are measured and monitored according to quartz crystal oscillation frequency changes with an evaporation rate frequency resolution of 0.01 nm/s. Six rotary crystal film thickness sensors of the quartz crystal monitoring system are able to improve accuracy of film thickness, so as to control an error within 0.1 nm.

Preferred embodiments of the external film system of the substrate 1:

The ultraviolet proof film material on the external surface of the substrate 1 according to the preferred embodiments:

Preferred embodiment 1: silicon oxide 20%, zirconium oxide 80%.

Preferred embodiment 2: silicon oxide 80%, zirconium oxide 20%.

Preferred embodiment 3: silicon oxide 50%, zirconium oxide 50%.

The blue light proof film material on the external surface of the substrate 1 according to the preferred embodiments:

Preferred embodiment 1: tin oxide 30%, rubidium 40%, platinum 30%.

Preferred embodiment 2: tin oxide 60%, rubidium 10%, platinum 30%.

Preferred embodiment 3: tin oxide 55%, rubidium 35%, platinum 10%.

The optical regulation film material on the external surface of the substrate 1 according to the preferred embodiments:

Preferred embodiment 1: aluminum 40%, silicon oxide 60%.

Preferred embodiment 2: aluminum 60%, silicon oxide 40%.

Preferred embodiment 3: aluminum 50%, silicon oxide 50%.

The anti-oil film material on the external surface of the substrate 1 according to the preferred embodiments:

Preferred embodiment 1: magnesium fluoride 60%, zirconium oxide 40%.

Preferred embodiment 2: magnesium fluoride 80%, zirconium oxide 20%.

Preferred embodiment 3: magnesium fluoride 70%, zirconium oxide 30%.

Preferred embodiments of the internal film system of the substrate 1:

The ultraviolet proof film material on the internal surface of the substrate 1 according to the preferred embodiments:

Preferred embodiment 1: silicon oxide 20%, zirconium oxide 80%.

Preferred embodiment 2: silicon oxide 80%, zirconium oxide 20%.

Preferred embodiment 3: silicon oxide 50%, zirconium oxide 50%.

The blue light proof film material on the internal surface of the substrate 1 according to the preferred embodiments:

Preferred embodiment 1: tin oxide 30%, rubidium 40%, platinum 30%.

Preferred embodiment 2: tin oxide 60%, rubidium 10%, platinum 30%.

Preferred embodiment 3: tin oxide 55%, rubidium 35%, platinum 10%.

The anti-oil film material on the internal surface of the substrate 1 according to the preferred embodiments:

Preferred embodiment 1: magnesium fluoride 60%, zirconium oxide 40%.

Preferred embodiment 2: magnesium fluoride 80%, zirconium oxide 20%.

Preferred embodiment 3: magnesium fluoride 70%, zirconium oxide 30%.

What is claimed is:

1. A method for manufacturing a blue light proof optical lens, which forms the blue light proof optical lens by providing vapor deposition on both an external surface and an internal surface of a substrate, comprising steps of:
1) cleaning the substrate;
2) drying the substrate after cleaning; specifically, dehydrating the substrate with isopropanol after cleaning, and then slowly pulling out of the isopropanol for drying;
3) before deposition, cleaning the substrate in a vacuum chamber of a vacuum deposition machine; specifically, after the substrate is dried by slowly pulling out of the isopropanol, placing the substrate inside the vacuum chamber of the vacuum deposition machine, adjusting a vacuum degree inside the vacuum chamber to no more than 9.5×10⁻³Pa, then cleaning the substrate with an ion source; and
4) coating the substrate, comprising steps of coating an external film system and coating an internal film system; wherein
A) coating the external film system comprises steps of: coating an impact strengthening external film, coating an ultraviolet proof external film, coating a blue light proof external film, coating an optical regulation external film, and coating an anti-oil external film in sequence; wherein
A1) coating the impact strengthening external film comprises steps of: adjusting the vacuum degree in the vacuum chamber to no more than 2.0×10⁻³Pa, evaporating an impact strengthening film material with an electron gun; and then depositing the impact strengthening film material on the external film surface of the substrate in a nano-molecular form with the ion source, so as to form the impact strengthening external film;
wherein a thickness thereof is 0.1-600 nm; and the impact strengthening film material is silicon oxide;
A2) coating the ultraviolet proof external film comprises steps of: evaporating an ultraviolet proof film material with the electron gun; and then depositing the ultraviolet proof film material on the impact strengthening external film of the step A1) in the nano-molecular form with the ion source, so as to form the ultraviolet proof external film; wherein a thickness thereof is 0.1-600 nm; and the ultraviolet proof film material comprises silicon oxide with a content of 20-80%, and zirconium oxide with a content of 20-80%;
A3) coating the blue light proof external film comprises steps of: evaporating a blue light proof film material with the electron gun; and then depositing the blue light proof film material on the ultraviolet proof external film of the step A2) in the nano-molecular form with the ion source, so as to form the blue light proof external film;
wherein a thickness thereof is 0.1-600 nm; and the blue light proof film material comprises tin oxide with a content of 30-60%, rubidium with a content of 10-40%, and platinum with a content of 10-40%;
wherein the step A3) is repeated at least once for forming a blue light proof external film stack with at least two layers;
A4) coating the optical regulation external film comprises steps of: evaporating an optical regulation film material with the electron gun; and then depositing the optical regulation film material on the blue light proof external film of the step A3) in the nano-molecular form with the ion source, so as to form the optical regulation external film;
wherein a thickness thereof is 0.1-600 nm; and the blue light proof film material comprises aluminum with a content of 40-60%, and silicon oxide with a content of 40-60%;
A5) coating the anti-oil external film comprises steps of: evaporating an anti-oil film material with the electron gun; and then depositing the anti-oil film material on the optical regulation external film of the step A4) in the nano-molecular form with the ion source, so as to form the anti-oil external film; wherein a thickness thereof is 0.1-600 nm; and the blue light proof film material comprises magnesium fluoride with a content of 60-80%, and zirconium oxide with a content of 20-40%;
after coating the anti-oil external film, the external film system is complete, and the internal film system is to be coated;
B) coating the internal film system comprises steps of: coating an impact strengthening internal film, coating an ultraviolet proof internal film, coating a blue light proof internal film, and coating an anti-oil internal film in sequence; wherein
B1) coating the impact strengthening internal film comprises steps of: evaporating the impact strengthening film material with the electron gun; and then depositing the impact strengthening film material on the internal film surface of the substrate in the nano-molecular form with the ion source, so as to form the impact strengthening internal film; wherein a thickness thereof is 0.1-600 nm; and the impact strengthening film material is silicon oxide;
B2) coating the ultraviolet proof internal film comprises steps of: evaporating the ultraviolet proof film material with the electron gun; and then depositing the ultraviolet proof film material on the impact strengthening internal film of the step B1) in the nano-molecular form with the ion source, so as to form the ultraviolet proof internal film; wherein a thickness thereof is 0.1-600 nm; and the ultraviolet proof film material comprises silicon oxide with a content of 20-80%, and zirconium oxide with a content of 20-80%;
B3) coating the blue light proof internal film comprises steps of: evaporating the blue light proof film material with the electron gun; and then depositing the blue light proof film material on the ultraviolet proof internal film of the step B2) in the nano-molecular form with the ion source, so as to form the blue light proof internal film; wherein a thickness thereof is 0.1-600 nm; and the blue light proof film material comprises tin oxide with a content of 30-60%, rubidium with a content of 10-40%, and platinum with a content of 10-40%;
wherein the step B3) is repeated at least once for forming a blue light proof internal film stack with at least two layers;
B4) coating the anti-oil internal film comprises steps of: evaporating the anti-oil film material with the electron gun; and then depositing the anti-oil film material on the blue light proof internal film of the step B3) in the nano-molecular form with the ion source, so as to form the anti-oil internal film; wherein a thickness thereof is 0.1-600 nm; and the blue light proof film material comprises magnesium fluoride with a content of 60-80%, and zirconium oxide with a content of 20-40%.

2. The method, as recited in claim 1, wherein in the step 1), cleaning the substrate specifically comprises steps of:
a) cleaning the substrate with organic detergent, and using ultrasound for assisting;
b) after the step a), cleaning the substrate with water-based detergent, and using the ultrasound for assisting; and
c) after the step b), rinsing the substrate with city water and distilled water in sequence.

3. The method, as recited in claim 1, wherein the substrate is formed with polymer resin.
